(19) United States
(12) Patent Application Publication
(10) Pub. No.: US 2026/0196259 A1
(43) Pub. Date: Jul. 9, 2026

(54) HEALTH SCAN OF A MEMORY DEVICE USING A CODE WORD ERROR RATE MACHINE LEARNING MODEL

(71) Applicant: Micron Technology, Inc., Boise, ID (US)

(72) Inventors: Li-Te Chang, San Jose, CA (US); Murong Lang, San Jose, CA (US); Zhenming Zhou, San Jose, CA (US)

(21) Appl. No.: 19/015,283

(22) Filed: Jan. 9, 2025

(51) Int. Cl. G11C 11/406

(52) U.S. Cl. CPC G11C 11/40618; G11C 11/40615; G11C 11/40626

(57) ABSTRACT

A system includes a memory device comprising a plurality of dies and a processing device coupled to the memory device. The processing device provides updated assignments of a plurality of blocks from a plurality of dies to a plurality of voltage offset bins to a code word error rate (CWER) machine learning (ML) model. The processing device receives, from the CWER ML model, a CWER distribution of the memory device. The processing device determines a tail slope value associated with the CWER distribution. The processing device determines whether the tail slope value satisfies a tail slope threshold criterion. Responsive to determining that the tail slope value associated with the CWER distribution satisfies the tail slope threshold criterion, the processing device causes a data associated with a block family to be refreshed.

### TECHNICAL FIELD

Embodiments of the disclosure relate generally to memory sub-systems, and more specifically, to a health scan of a memory device using a code word error rate (CWER) machine learning ML model.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments.

FIG. 1B is an example memory sub-system controller of the computing system that is configured to direct training a code word error rate (CWER) machine learning (ML) model for use in health scan monitoring in accordance with some embodiments.

FIG. 1C is an example neural network that is useable to train the CWER ML model in accordance with some embodiments.

FIG. 2 is a flow diagram of an example method of employing ML-based system health monitoring in accordance with various embodiments.

FIG. 3A is a bar graph depiction of a histogram of voltage offset bins for block families of the memory device in accordance with some embodiments.

FIG. 3B illustrates graphs corresponding to example memory device-level CWER distribution outputs from the CWER ML model based on a correlation between the CWER profile of a die and the voltage offset bins of the histogram in accordance with some embodiments.

FIG. 4 is a pictorial representation of voltage offset bin distribution that groups voltage offset bins into block families and block families into die families in accordance with some embodiments.

FIG. 5 is a block diagram of an example computer system in which embodiments of the present disclosure can operate.

### DETAILED DESCRIPTION

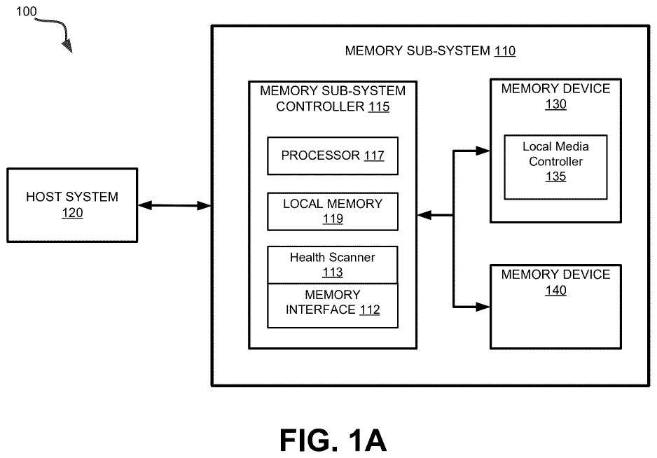

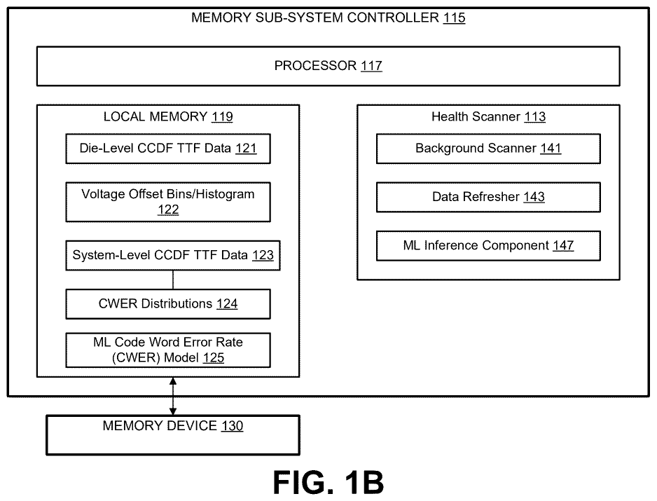

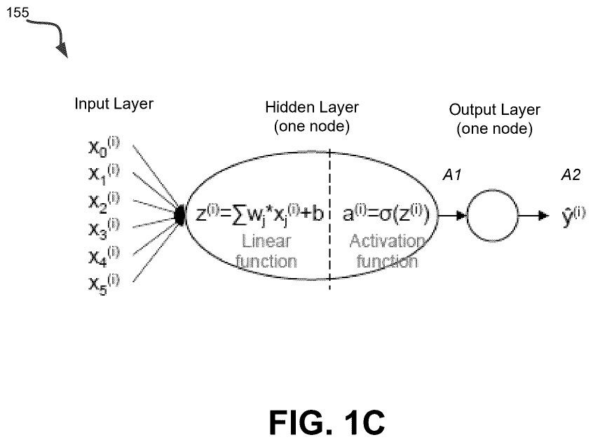

Aspects of the present disclosure are directed to performing a health scan of a memory device in a memory sub-system using a code word error rate (CWER) machine learning (ML) model in accordance with some embodiments. A memory sub-system can be a storage device, a memory module, or a combination of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high-density, non-volatile memory devices where retention of data is desired when no power is supplied to the memory device. For example, NAND memory, such as 3D flash NAND memory, offers storage in the form of compact, high-density configurations. A non-volatile memory device is a package of one or more memory dies, each including one or more planes. For some types of non-volatile memory devices (e.g., NAND devices), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1,” or combinations of such values.

A memory device can include multiple cells arranged in a two-dimensional or a three-dimensional grid. Memory cells are formed onto a silicon wafer in an array of columns and rows. A data block hereinafter refers to a unit of the memory device used to store data and can include a group of memory cells, a wordline group, a wordline, or individual memory cells. Each data block can include a number of sub-blocks, where each sub-block is defined by a set of associated pillars (e.g., one or more vertical conductive traces) extending from a shared bitline. Memory pages (also referred to herein as “pages”) store one or more bits of binary data corresponding to data received from the host system. To achieve high density, a string of memory cells in a non-volatile memory device can be constructed to include a number of memory cells at least partially surrounding a pillar of channel material. The memory cells can be coupled to access lines, which are commonly referred to as “wordlines,” often fabricated in common with the memory cells, so as to form an array of strings in a block of memory. The compact nature of certain non-volatile memory devices, such as 3D flash NAND memory, means wordlines are common to many memory cells within a block of memory.

In programming memory, memory cells can generally be programmed as single-level cells (SLC) or multiple-level cells (MLC). Thus, data states may be associated with certain logical levels of multi-cell memory such as L0, L1, L2, and so forth. Single-level cells can use a single memory cell to represent one digit (e.g., bit) of data. Multiple-level cells use more than two Vt ranges, where each Vt range indicates a different data state (or logical level). So, for example, four-level MLC can store two bits. Similarly, eight-level MLC (referred to as TLC) can represent a bit pattern of three bits, including a first digit, e.g., a least significant bit (LSB) or lower page (LP) data; a second digit, e.g., upper page (UP) data; and a third digit, e.g., a most significant bit (MSB) or extra page (XP) data. Similarly, sixteen-level MLC (typically referred to as QLC) can represent a bit pattern of four bits, and 32-level MLC (typically referred to as PLC) can represent a bit pattern of five bits. Programming MLC memory can be performed using more than one programming pass and moving MLC-based data between memory locations can be referred to as folding the data due to the multiple programming passes employed to obtain the threshold voltage levels that depict the desired logical level (e.g., data states) of the moved data. A window margin (e.g., a certain number of volts) such as a dead space can separate adjacent Vt ranges to facilitate differentiating between data states. Multiple-level cells can take advantage of the analog nature of traditional non-volatile memory cells by assigning a bit pattern to a specific Vt range.

Because of the phenomenon known as slow charge loss (“SCL”), the threshold voltage of a memory cell changes in time as the electric charge of the cell is degrading, which is referred to as “temporal voltage shift” (since the degrading electric charge causes the voltage distributions to shift along the voltage axis towards lower voltage levels). Temporal voltage shift (TVS) herein shall refer to a change in the measured voltage of cells as a function of time. Temporal voltage shift can include different components such as intrinsic charge loss, system charge loss, quick charge loss, and the like. Memory formed from certain NAND technologies generally exhibits more TVS than floating gate NAND. TVS is generally increased by program erase cycles (PEC), higher temperatures, and higher program voltages. TVS shows significant die-to-die variation. In memory that exhibits TVS, the threshold voltage is changing rapidly at first (immediately after the memory cell was programmed), and then slows down in an approximately logarithmic linear fashion with respect to the time elapsed since the cell programming event. If not mitigated, the temporal voltage shift caused by the slow charge loss can result in the increased bit error rate in read operations.

Temporal voltage shift can be mitigated by implementing a memory sub-system that employs block family based error avoidance strategies, thus significantly improving the bit error rate exhibited by the memory sub-system. The temporal voltage shift can be selectively tracked for a programmed set of memory cells grouped by block families. Appropriate voltage “read level offsets,” which are based on block affiliation with a certain block family, are applied to the base read levels to perform read operations. “Block” herein shall refer to a set of contiguous or non-contiguous memory pages. An example of “block” is “erasable block,” which is the minimal erasable unit of memory, while “page” is a minimal writable unit of memory. Each page includes of a set of memory cells. “Block family” (or “BF”) herein shall refer to a possibly noncontiguous set of memory cells that have been programmed within a specified time window and a specified temperature window, and thus are expected to exhibit similar or correlated changes in their respective data state metrics. A block family can be made with any granularity, containing only whole codewords, whole pages, whole super pages, or whole superblocks, or any combination of these granularities.

“Read level” herein shall refer to a voltage position. Read levels are numbered in increasing voltage from L1 through 2ⁿ, wherein n is the number of bits that can be stored in the cell. “Read level value” herein shall refer to a voltage or DAC value representing a voltage that is applied to the read element (often, the control gate for a NAND cell) for purposes of reading that cell. “Read level offset” herein shall refer to a component of the equation that determines the read level value. “Calibration” herein shall refer to altering a read level value (possibly by adjusting a read level offset or read level base) to better match the ideal read levels for a read or set of reads.

“Bin” (or “voltage bin” or “voltage offset bin”) herein shall refer to a set of read level offsets that are applied to a set of data. The bin offsets are read level offsets that affect the read level for block families within the bin. An old or older bin is one where the read level offsets are directed at data that was written at a relatively early time. A young or younger bin is one where the read level offsets are directed at data written relatively recently. “Bin selection” or “bin assignment” herein shall refer to the process by which the memory device selects which bin to use for a given read at a particular memory block. A “bin histogram” of voltage offset bins can be maintained that tracks which blocks are currently assigned to which voltage offset bin and can be updated over time.

Existing memory systems rely on data refresh mechanisms that initiate a refresh operation when a single page scan detects a Bit Error Count (BEC) exceeding a predefined threshold. While this approach effectively mitigates data retention issues, it presents several significant drawbacks. Frequent refresh operations, especially in multi-level cell (MLC) memories, require multiple programming passes, which can substantially degrade system performance by increasing latency and reducing input-output operations per second (IOPS). Additionally, the repetitive program/erase cycles (PEC) resulting from continuous refreshing accelerate wear and stress on memory cells, thereby diminishing the overall lifespan and endurance of the memory device. Furthermore, the limited sampling capabilities of background health scans may not promptly detect all data retention issues, leading to excessive data folding and adversely impacting the Quality of Service (QoS) of the memory device.

Furthermore, memory cells are susceptible to temporal voltage shift or data retention degradation. This can be caused by slow charge loss or changes in temperature. As such, this can result in the increased bit error rate in read operations. As data integrity diminishes, the system must perform more frequent data refresh operations, such as rewriting data to new memory cells. These refresh operations not only impose additional computational overhead but also risk introducing errors during the reprogramming process.

As a result of these issues, existing systems may experience excessive data folding. This excessive folding can degrade Quality of Service (QoS) by introducing unnecessary latency and reducing system responsiveness. Moreover, it negatively impacts the endurance of the memory device by accelerating wear through increased program/erase cycles. Consequently, the memory's operational lifespan is shortened, and overall system reliability is compromised.

Aspects of the present disclosure address the above and other deficiencies. The component-to-system code word error rate (CWER) machine learning (ML) model is able to take voltage offset bins, which are assigned to each read sample of a health scan performed over time, and predict a corresponding CWER distribution for the memory device. The CWER distribution can be understood as a distribution of BEC for the memory device over time. In some embodiments, the CWER distribution is generated as a complementary cumulative distribution function (CCDF), which can be used to describe the tail distribution of a variable. In the context of data retention rates in NAND memory, the CCDF can be particularly useful for understanding the reliability and failure characteristics of a memory device over time. For example, a tail slope can be measured using the CWER distribution. By measuring a tail slope value of the CWER distribution and comparing the tail slope value with a threshold value, the memory sub-system system can determine whether to refresh data of a particular block family, block, or page depending on granularity of background health scans, memory device, and application.

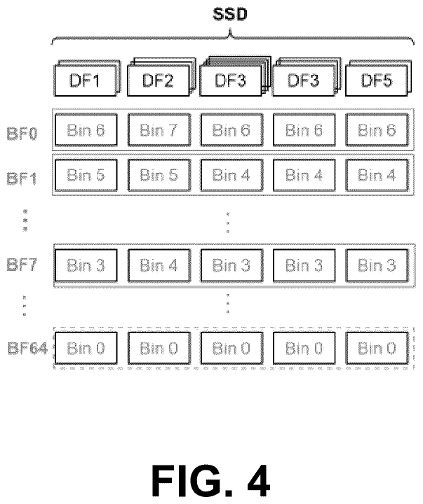

In some embodiments, the system (e.g., controller) detects an occurrence of a trigger event that causes a health scan to be performed on a block family of a plurality of block families of a memory device that includes a plurality of dies. The system can then update, for each read sample taken during the health scan of the block family, an assignment of a voltage offset bin of a plurality of voltage offset bins. In some embodiments, each respective voltage offset bin of the plurality of voltage offset bins can also be associated with a die family of the plurality of dies (see FIG. 4).

In various embodiments, these voltage offset bins are tracked within the previously mentioned bin histogram. More specifically, coarse read calibration may be performed using a set of predefined read levels, where each voltage offset bin points to a set of read offsets associated with voltage levels, e.g., L0, L1, . . . L7, which were discussed. Because the memory device having multiple dies and blocks of data with different SCL characteristics, the system (e.g., controller) can group similar blocks together (e.g., by time and temperature) in a block family and apply a closest read voltage offset or selected bin for that block family. While a histogram is referenced herein, it should be apparent that other data structures can be employed by which to track voltage offset bin assignments to blocks, block families, die families, and the like over time.

In some embodiments, the system further provides the updated assignments to the plurality of voltage offset bins into a CWER ML model, as was discussed. The system can then receive from the CWER ML model, a CWER distribution of the memory device. In some embodiments, in response to determining that the tail slope value associated with the CWER distribution satisfies a threshold value, the system causes a data associated with the block family to be refreshed. In other embodiments, in response to determining that a tail slope value associated with the CWER distribution fails to satisfy the threshold value, the system executes the CWER ML model with a set of updated assignments of the read samples to the plurality of voltage offset bins for the block family, thus avoiding premature data refresh.

Advantages of the present disclosure include, but are not limited to system-level data retention issues can be identified earlier while avoiding unnecessary data refresh operations that would otherwise impact performance and lifespan of the memory device. Furthermore, the disclosed embodiments can significantly save system resources by replacing other background management, such as media scans (related to detecting SCL) and partial read disturb detection (pRDD)-based scanning. Other advantages will be apparent based on the additional details provided herein.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface component 112. Memory interface component 112 is responsible for handling interactions of memory sub-system controller 115 with the memory devices of memory sub-system 110, such as memory device 130. For example, memory interface component 112 can send memory access commands corresponding to requests received from host system 120 to memory device 130, such as program commands, read commands, or other commands. In addition, memory interface component 112 can receive data from the memory device 130, such as data retrieved in response to a read command or a confirmation that a program command was successfully performed. In some embodiments, the memory sub-system controller 115 includes at least a portion of the memory interface 112. For example, the memory sub-system controller 115 can include a processor 117 (processing device) configured to execute instructions stored in local memory 119 for performing the operations described herein. In some embodiments, the memory interface component 112 is part of the host system 110, an application, or an operating system.

In one embodiment, the memory sub-system controller 115 includes a memory device health scanner 113 that can, in conjunction with the memory interface 112, oversee, control, and/or manage read access operations, such as read operations and scan read operations, performed on a non-volatile memory device, such as memory device 130, of the memory sub-system 110. In various embodiments, the memory sub-system controller 115 includes at least a portion of the health scanner 113 and is configured to perform the functionality described herein, particularly in relation to performing a health scan of a memory device 130 using a CWER ML model. In such embodiments, the health scanner 113 can be implemented using hardware or as firmware, stored on in the local memory 119 and/or in the memory device 130, executed by the health scanner 113 to perform the operations described herein. In some embodiments, one or more operations performed by the health scanner 113 are performed by the local media controller 135 or other logic located on-board the memory device 130.

FIG. 1B is an example memory sub-system controller 115 of the computing system 100 that is configured to direct training a machine learning (ML) code word error rate (CWER) model for use in health scan monitoring in accordance with some embodiments. FIG. 1C is an example neural network that is useable to train the CWER ML model according to some embodiments. In some embodiments, the local memory 119 (and/or the memory device 130) stores data used to train and use the CWER ML model. For example, the local memory 119 can include volatile memory, such as static random access memory (SRAM), dynamic RAM (DRAM), and/or tightly-coupled memory (TCM). Depending on the volume of this data, at least some of the data can be stored in the memory device 130, which can also provide non-volatile backup storage to the local memory 119.

In various embodiments, the data used to train (or that results from the trained) TR ML model 125 can include component-level CCDF TTF data 121, voltage offset bins 122 (which can be in a histogram form), system-level CCDF TTF data 123, and related system-level CWER distributions 124. In some embodiments, the health scanner 113 includes, but is not limited to, a background scanner 141 for performing background health scans, a data refresher 143 to direct data refresh when a background health scan finds a unit of memory (e.g., related to a block family (BF) and/or a die family (DF)) that meets certain BEC or other aging criteria, and a ML inference component 147.

In embodiments, a neural network (NN) is executed to train the CWER ML model 125 with particular weights and bias values, as will be discussed in more detail. The health scanner 113 can group blocks together based on, for example, being programmed to one or more dies around a same time and temperature, which will be discussed in more detail with reference to FIG. 4.

In embodiments, the CWER ML model 125 is trained using die (e.g., memory component) and sub-system inputs provided by the memory sub-system controller. In some implementations, labeled read samples are generated to create labeled inputs, which are then processed by a multi-layer neural network 155, as depicted in FIG. 1C. In some embodiments, the system stores a set of weights and bias values, derived after multiple iterations of training the multi-layer neural network 155, as part of the CWER ML model 125. These weights and biases may correspond to a linear function and activation function within the hidden layer and output layer of the trained network. Although a two-layer neural network is shown in FIG. 1C, other configurations, including additional hidden layers or different types of neural networks, are also possible and are provided for illustrative purposes only.

In some embodiments, training the CWER ML model 125 comprises generating training data through conditioning the memory device to simulate use, collecting CWER data from individual components, and organizing it with related parameters. For example, this can include conditioning the dies with repeated program-erase cycles, applying heat to accelerate aging, and adjusting read parameters to analyze their impact on performance. The CWER ML model 125 machine learning model is trained using the collected CWER data. In some embodiments, this data is labeled with key metrics for supervised training.

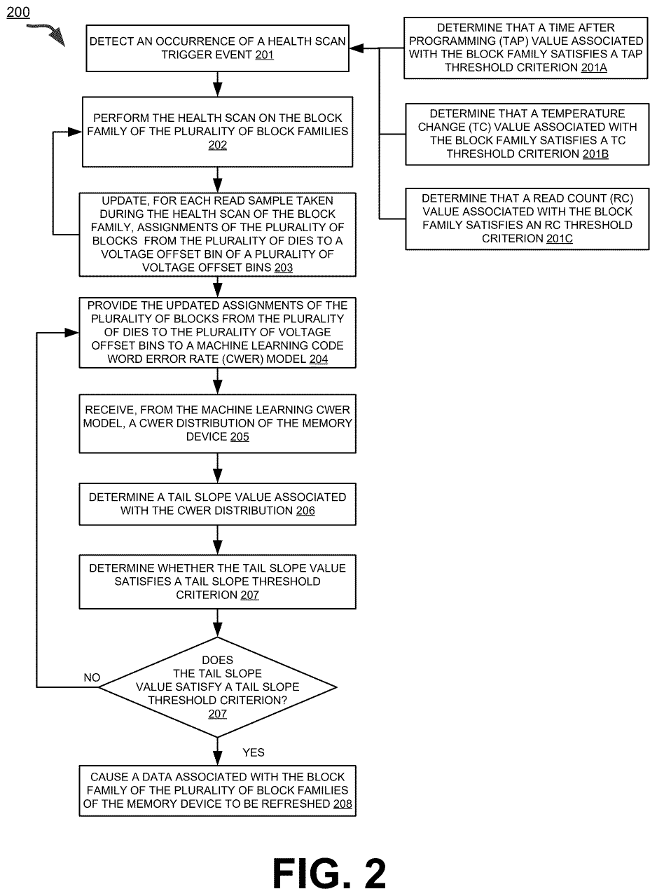

FIG. 2 is a flow diagram of an example method 200 of performing a health scan of a memory device using a CWER ML model in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the health scanner 113 with access to the local memory 119 and the memory device 130 of FIG. 1A. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

In some embodiments, at operation 201, the processing logic detects an occurrence of a health scan trigger event. In some embodiments, the processing logic monitors for trigger events at time intervals. In some embodiments, the processing logic monitors for trigger events continuously. In some embodiments, the processing logic monitors for trigger events in response to a host input.

In some embodiments, at operation 201A, the processing logic triggers a health scan upon determining that a time after programming (TAP) value associated with the block family satisfies a TAP threshold criterion, wherein the TAP threshold criterion is a maximum TAP value. The TAP value represents the duration that has elapsed since data was last programmed to a memory cell within a block family. In some embodiments, the TAP threshold criterion is predetermined (e.g., based on system requirements or the specific endurance characteristics of the memory device). In some embodiments, satisfying the TAP threshold criterion entails a TAP value that is greater than the maximum TAP value. Conversely, failing to satisfy the TAP threshold criterion entails a TAP value equal to or less than the maximum TAP value. Responsive to failing to satisfy the TAP threshold criterion, the processing logic does not initiate a health scan, instead continuing to monitor for trigger events.

In some embodiments, at operation 201B, the processing logic triggers a health scan upon determining that a temperature change (TC) value associated with the block family satisfies a TC threshold criterion. In some embodiments, the TC value is a change in temperature since the block family was programmed and the TC threshold criterion is a maximum TC value. In some embodiments, if the TC value exceeds the maximum TC threshold, the processing logic performs the health scan at operation 202. Conversely, if the TC value is equal to or less than the threshold, the criterion is not satisfied, and no health scan is performed, with the system continuing to monitor for future trigger events.

In some embodiments, at operation 201C, the processing logic triggers a health scan upon determining that a read count (RC) value associated with the block family satisfies an RC threshold criterion. In some embodiments, the RC value represents the number of read operations performed on the block family since it was programmed and the RC threshold criterion is a maximum RC value (e.g., a maximum number of read operations performed on the block family since programming). In some embodiments, if the RC value exceeds the maximum RC threshold, the RC threshold criterion is satisfied and the processing logic initiates a health scan (at operation 202). Conversely, if the RC value is equal to or less than the threshold, the RC threshold criterion is not satisfied, and no health scan is performed, with the system continuing to monitor for future trigger events.

In some embodiments, at operation 202, the processing logic performs the health scan on a block family of the plurality of block families of the memory device 130. In some embodiments, the health scan is used to generate read samples indicative of data retention levels of the BF. In embodiments, the block family comprises a plurality of blocks residing within one or more dies of the plurality of dies. The health scan process can vary across different embodiments. In some implementations, the health scan is conducted specifically on the bin that has the lowest page bit error count. In some embodiments, this bin is selected from a number of adjacent bins.

In some embodiments, at operation 203, the processing logic updates, for each read sample taken during the health scan of the block family, the assignments of a plurality of blocks from the plurality of dies to a voltage offset bin of the plurality of voltage offset bins. In some embodiments, a block family includes a distribution of bins (which are associated with a voltage offset bin) that are distributed across multiple dies. In embodiments, the updated assignments to the plurality of voltage offset bins are tracked within a bin histogram, as discussed herein. The bin histogram tracks which blocks are currently assigned to which voltage offset bin and can be updated over time.

The method 200 can flow back to operation 202 while there are still samples for which to update voltage offset bin assignments. In some embodiments, even after the method 200 flows on to operation 204, operations 202 and 203 may continue to be performed.

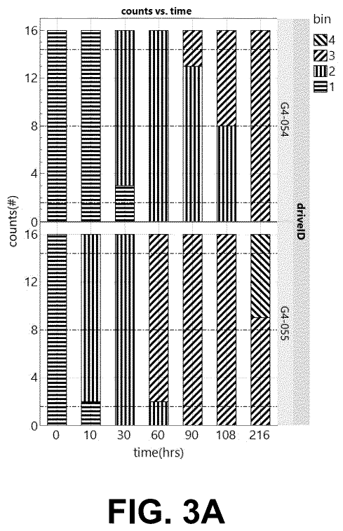

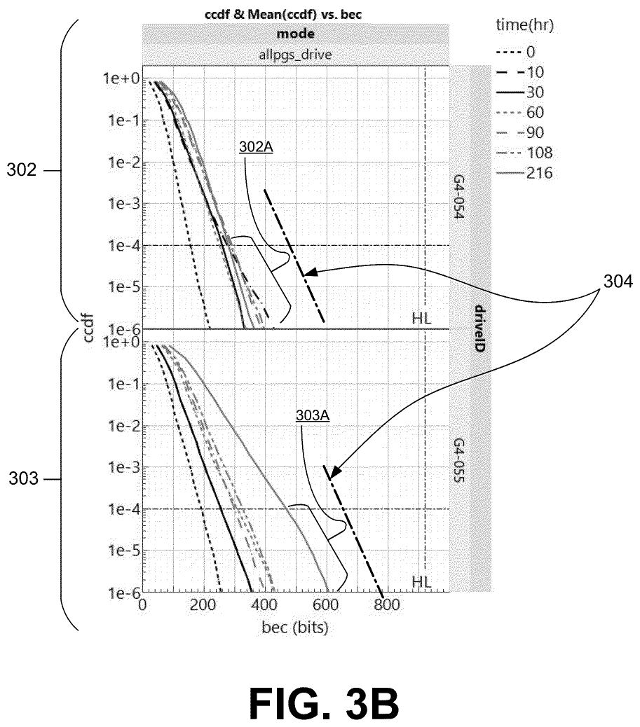

FIG. 3A is a bar graph depiction of a histogram of voltage offset bins for block families. The histogram is illustrated with four different bin values, each associated with a voltage offset bin. Each voltage offset bin can correspond to a set of voltage offsets for different read levels, e.g., L0, L1, . . . L7, or the like. Thus, voltage offset bins might also correlate to ranges of program/erase (P/E) cycles, error rates, and/or retention times, as a given block family may have in common. Other data structures besides a histogram may also be configured to convey this information by way of voltage offset bins.

With specific reference to the histogram of voltage offset bins in FIG. 3A, the x-axis can represent the different voltage offset bins or categories and the y-axis can represent the frequency or count of blocks falling into each voltage offset bin. Further, the x-axis illustrates time after program of data in each block. In this way, assignments of blocks to a voltage offset bin tend to move into higher bins (indicative of aging data) over time, e.g., as the health scan progresses. In this way, higher bin values may be indicative of higher RBER and potentially getting closer to needing a data refresh.

At operation 204, the processing logic provides the updated assignments—of the plurality of blocks from the plurality of dies to the to the plurality of voltage offset bins—to the CWER ML model. The processing logic executes the CWER ML model using, as an input, the most-recent updates reflected in the bin assignments within the bin histogram received at operation 203.

At operation 205, the processing logic receives, from the CWER ML model, a CWER distribution of the memory device. In some embodiments, the processing logic outputs, from the CWER ML model, a system-level CWER distribution, which is statistical distribution of error rate across the plurality of dies of the memory device 130.

In some embodiments, the CWER distribution comprises a complementary cumulative distribution function (CCDF) of a bit error count (BEC) of the plurality of dies, and wherein the CCDF of the BEC is predictive of a likelihood of data retention past a particular time after program of the data to the memory device 130. FIG. 3B illustrates graphs corresponding to example memory device-level CWER distribution outputs from the CWER ML model based on a correlation between the CWER profile of a die and the voltage offset bins of the histogram in accordance with some embodiments. In embodiments, the CWER distribution includes a plot of a complementary cumulative distribution function (CCDF) of a bit error count (BEC) of the plurality of dies of the memory device 130.

More specifically, with reference to FIG. 3B, the different plot lines are associated with a different time after program, e.g., different data retention time. As illustrated, the y-axis represents a range of CCDF values and the x-axis represents bit error count (BEC) values. The CCDF value of a variable X (which here can represent a tail of BEC probability distribution) can be defined as: CCDF(x)=P(X>x). This function gives the probability that the variable X (e.g., BEC) takes on a value greater than x. Thus, the CCDF value shows how likely it is for the variable X to exceed a certain threshold value.

For example, with reference to FIG. 3B, in CWER distribution 303, at the CCDF value of 1e−4, the CWER ML model predicts a BEC of ~500 bits. In simpler terms, the CWER ML model predicts that 0.01% of the time (or for 1 out of every 10,000 observations), the BEC will be 500 bits or higher. This is in contrast with CWER distribution 302 where, at the CCDF value of 1e−4, the CWER ML model predicts a BEC of ~400 bits. In simpler terms, the CWER ML model predicts that 0.01% of the time (or for 1 out of every 10,000 observations), the BEC will be ~400 bits or higher.

At operation 206, the processing logic determines a tail slope value associated with the CWER distribution, as discussed with reference to FIG. 3B (e.g., tail slopes 302A and 303B from CWER distributions 302 and 303, respectively). In some embodiments, the tail slope value represents a rate at which a probability of a BEC decreases with increasing BEC values at a data retention time. In some embodiments, the tail slope value is measured in bits per decade, indicating how many bits' worth of error counts the probability decreases for each tenfold increase in the BEC value.

In some embodiments, to determine a tail slope value associated with a CWER distribution, within an identified region, a linear regression is performed on the plot of data points corresponding to a data retention time. This involves fitting a straight line to the data points of the identified region. The slope of this line is the tail slope value. For example, in CWER distribution 302, the identified region from which the tail slope value is determined is tail slope 302A. Other embodiments can use other methods for determining the tail slope value. Other embodiments can use other identified regions for determining the tail slope value.

A higher tail slope value (e.g., steeper slope) implies that the probability of observing higher Bit Error Counts decreases more rapidly. In other words, as you move along the x-axis (increasing BEC), the CCDF value (on the y-axis) drops off quickly. This is illustrated in CWER distribution 302 of FIG. 3B.

A lower tail slope value (e.g., flatter slope) indicates that the probability decreases more slowly, meaning higher error counts are more common. This is illustrated in CWER distribution 303 of FIG. 3B.

At operation 207, the processing logic determines whether the tail slope value satisfies a tail slope threshold criterion. In some embodiments, the tail slope value satisfies the tail slope threshold criterion when the tail slope value is greater than or equal to a minimum allowable tail slope value. In some embodiments, the minimum allowable tail slope value is predetermined. When the tail slope value meets or exceeds the tail slope threshold criterion, it indicates that the probability of high error counts decreases rapidly enough to be reliable. A rapid decrease means that as higher BEC values are considered (e.g., moving further into the tail of the CWER distribution), the probability of encountering such error counts drops significantly (e.g., a steeper curve at a data retention time). The CWER distribution 302 with a high tail slope 302A illustrates a tail slope value that satisfies the tail slope threshold criterion (e.g., the tail slope value 302A is greater than or equal to the minimum allowable tail slope value 304).

When the tail slope value is less than the minimum allowable threshold (the criterion), it signifies that the probability of encountering high bit error counts (BEC) decreases too slowly as the error count increases. This gradual decline means that higher BECs remain relatively probable, which can overwhelm the system's error correction capabilities. As a result, the system is at a higher risk of experiencing errors that could lead to data loss and other errors. The CWER distribution 303 with a low tail slope 303A illustrates a tail slope value that fails to satisfy the tail slope threshold criterion (e.g., the tail slope value 303A is less than the minimum allowable tail slope value 304).

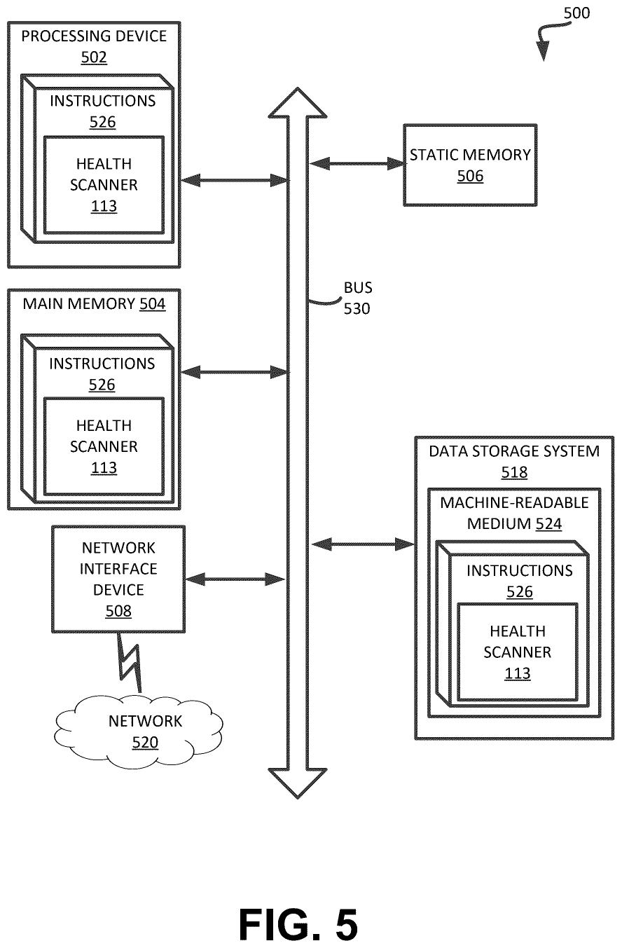

Responsive to determining that the tail slope value satisfies the tail slope threshold criterion, at operation 208, the processing logic causes a data associated with the block family to be refreshed. A tail slope value less than the tail slope threshold criterion (e.g., a flatter tail slope from a greater number of bits per decade), indicates that there will be memory cells at increasingly higher BECs. It signifies that the expected Bit Error Count (BEC) at the 1e−4 threshold level is already elevated, indicating a need to refresh data in blocks linked to the affected bin(s). (See FIG. 5 for more information on how block families suitable for individual refreshing are identified.) By refreshing the data, the processing logic can decrease the BEC at CCDF probabilities, steepening the tail slope of the error distribution (increasing the tail slope value), and bringing the tail slope value back above the minimum allowable tail slope value. In some embodiments, the processing logic monitors for additional conditions for performing operation 208 using the output of the CWER ML model. For example, in some embodiments, the processing logic can monitor for a satisfaction of a threshold condition associated with a trigger rate margin of the CWER distribution. In some embodiments, the TR margin can be measured as a distance from the CWER distribution at a particular CCDF value to a hard limit (HL) of a low-density parity-check (LDPC) decoder of the memory sub-system controller, e.g., processing device. By measuring a TR margin value of the CWER distribution and comparing the TR margin value with a threshold value, the memory sub-system system can determine whether to refresh data of a particular block family, block, or page depending on granularity of background health scans, memory device, and application. In some embodiments, other additional conditions are implemented.

Responsive to determining that the tail slope value fails to satisfy the tail slope threshold criterion, the processing logic executes the CWER ML model using a new set of updated assignments to a plurality of voltage offset bins. For example, the method 200 can loop back to operation 204 after additional read samples get updated voltage offset bin assignments at operation 203.

FIG. 4 is a pictorial representation of voltage offset bin distribution that groups voltage offset bins into block families and block families into die families in accordance with some embodiments. As illustrated, block families (BFs) can include a distribution of bins (which are associated with a voltage offset bin) that are simultaneously distributed across multiple dies, e.g., where each voltage offset bin can be associated with a die family (DF). In this way, to correlate the component CWER data to the system CWER data, the controller 115 can consider multiple dies, each assigned to a different voltage offset bin depending on BF assignment. This grouping of block families may be based on blocks of a BF being programmed around the same time and temperature, e.g., within a range of a time period and temperature range. In this way, each BF can be expected to have similar data retention length and read level values. Further, sampling at the BF level can be expected to be more efficient in being representative of the BF as a whole without having to sample all blocks of the block family.

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the health scanner 113 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium, such as a non-transitory computer-readable storage medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1A.

In one embodiment, the instructions 526 include instructions to implement functionality corresponding to the health scanner 113 of FIG. 1A). While the machine-readable storage medium 524 is shown in an example embodiment to be a single medium, the term “machine-readable storage medium” or “non-transitory computer-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device comprising a plurality of dies; and
a processing device coupled to the memory device, the processing device to perform operations comprising:
providing updated assignments of a plurality of blocks from the plurality of dies to a plurality of voltage offset bins to a code word error rate (CWER) machine learning (ML) model;
receiving, from the CWER ML model, a CWER distribution of the memory device; and
determining a tail slope value associated with the CWER distribution;
determining whether the tail slope value satisfies a tail slope threshold criterion; and
responsive to determining that the tail slope value associated with the CWER distribution satisfies the tail slope threshold criterion, causing data associated with a block family of a plurality of block families of the memory device to be refreshed, wherein the block family comprises a plurality of blocks residing within one or more dies of the plurality of dies.

2. The system of claim 1, wherein the CWER distribution comprises a complementary cumulative distribution function (CCDF) of a bit error count of the plurality of dies, and wherein the CCDF of the bit error count is predictive of a likelihood of data retention past a particular time after program of the data.

3. The system of claim 1, wherein the tail slope value represents a rate at which a probability of a bit error count (BEC) decreases with increasing BEC values at a data retention time, and wherein the tail slope value is measured in bits per decade.

4. The system of claim 1, wherein the processing device is to perform operations further comprising:
detecting an occurrence of a health scan trigger event;
performing the health scan on the block family of the plurality of block families; and
updating, for each read sample taken during the health scan of the block family, the assignments of the plurality of blocks from the plurality of dies to the voltage offset bin of the plurality of voltage offset bins.

5. The system of claim 1, wherein the tail slope value satisfies the tail slope threshold criterion when the tail slope value is greater than or equal to a minimum allowable tail slope value.

6. The system of claim 4, wherein detecting the occurrence of the health scan trigger event comprises:
determining that a time after programming (TAP) value associated with the block family satisfies a TAP threshold criterion, wherein the TAP threshold criterion is a maximum TAP value.

7. The system of claim 4, wherein detecting the occurrence of the health scan trigger event comprises:
determining that a temperature change (TC) value associated with the block family satisfies a TC threshold criterion, wherein the TC value is a change in temperature since the block family was programmed, and wherein the TC threshold criterion is a maximum TC value.

8. The system of claim 4, wherein detecting the occurrence of the health scan trigger event comprises:
determining that a read count (RC) value associated with the block family satisfies an RC threshold criterion, wherein the RC value is a number of read operations performed on the block family since the block family was programmed, and wherein the RC threshold criterion is a maximum RC value.

9. A method comprising:
providing, by a processing device, updated assignments of a plurality of blocks from a plurality of dies to a plurality of voltage offset bins to a code word error rate (CWER) machine learning (ML) model;
receiving, from the CWER ML model, a CWER distribution of a memory device; and
receiving, from the CWER ML model, a CWER distribution of the memory device; and
determining a tail slope value associated with the CWER distribution;
determining whether the tail slope value satisfies a tail slope threshold criterion; and
responsive to determining that the tail slope value associated with the CWER distribution satisfies the tail slope threshold criterion, causing data associated with a block family of a plurality of block families of the memory device to be refreshed, wherein the block family comprises a plurality of blocks residing within one or more dies of the plurality of dies.

10. The method of claim 9, wherein the CWER distribution comprises a complementary cumulative distribution function (CCDF) of a bit error count of the plurality of dies, and wherein the CCDF of the bit error count is predictive of a likelihood of data retention past a particular time after program of the data.

11. The method of claim 9, wherein the tail slope value represents a rate at which a probability of a bit error count (BEC) decreases with increasing BEC values at a data retention time, and wherein the tail slope value is measured in bits per decade.

12. The method of claim 9, wherein the tail slope value satisfies the tail slope threshold criterion when the tail slope value is greater than or equal to a minimum allowable tail slope value.

13. The method of claim 9, further comprising:
detecting an occurrence of a health scan trigger event;
performing the health scan on the block family of the plurality of block families; and
updating, for each read sample taken during the health scan of the block family, the assignments of the plurality of blocks from the plurality of dies to the voltage offset bin of the plurality of voltage offset bins.

14. The method of claim 13, wherein detecting the occurrence of the health scan trigger event comprises:
determining that a time after programming (TAP) value associated with the block family satisfies a TAP threshold criterion, wherein the TAP threshold criterion is a maximum TAP value.

15. The method of claim 13, wherein detecting the occurrence of the health scan trigger event comprises:
determining that a temperature change (TC) value associated with the block family satisfies a TC threshold criterion, wherein the TC value is a change in temperature since the block family was programmed, and wherein the TC threshold criterion is a maximum TC value.

16. The method of claim 13, wherein detecting the occurrence of the health scan trigger event comprises:
determining that a read count (RC) value associated with the block family satisfies an RC threshold criterion, wherein the RC value is a number of read operations performed on the block family since the block family was programmed, and wherein the RC threshold criterion is a maximum RC value.

17. A non-transitory computer-readable storage medium storing instructions, which when executed by a processing device coupled to a memory device of a memory sub-system, causes the processing device to perform operations comprising:
providing updated assignments of a plurality of blocks from a plurality of dies to a plurality of voltage offset bins to a code word error rate (CWER) machine learning (ML) model;
receiving, from the CWER ML model, a CWER distribution of the memory device; and
determining a tail slope value associated with the CWER distribution;
determining whether the tail slope value satisfies a tail slope threshold criterion; and
responsive to determining that the tail slope value associated with the CWER distribution satisfies the tail slope threshold criterion, causing data associated with a block family of a plurality of block families of the memory device to be refreshed, wherein the block family comprises a plurality of blocks residing within one or more dies of the plurality of dies.

18. The non-transitory computer-readable storage medium of claim 17, the operations further comprising:
detecting an occurrence of a health scan trigger event;
performing the health scan on the block family of the plurality of block families; and
updating, for each read sample taken during the health scan of the block family, the assignments of the plurality of blocks from the plurality of dies to the voltage offset bin of the plurality of voltage offset bins.

19. The non-transitory computer-readable storage medium of claim 17, wherein the CWER distribution comprises a complementary cumulative distribution function (CCDF) of a bit error count of the plurality of dies, and wherein the CCDF of the bit error count is predictive of a likelihood of data retention past a particular time after program of the data.

20. The non-transitory computer-readable storage medium of claim 17, wherein the tail slope value represents a rate at which a probability of a bit error count (BEC) decreases with increasing BEC values at a data retention time, and wherein the tail slope value is measured in bits per decade.
